(19) United States
(12) Patent Application Publication
(10) Pub. No.: US 2026/0282280 A1
(43) Pub. Date: Sep. 17, 2026

(54) COOLING APPARATUS FOR MULTI-CHIP/MULTI-MODULE HEAT DISSIPATION

(71) Applicant: BEIJING ZITIAO NETWORK TECHNOLOGY CO., LTD., Beijing (CN)

(72) Inventors: Shiqiang LI, Beijing (CN); Shifeng WANG, Beijing (CN); Ruidong WANG, Beijing (CN); Chenghua LIU, Beijing (CN); Yuanlin REN, Beijing (CN); Jian WANG, Beijing (CN)

(21) Appl. No.: 19/473,122

(22) PCT Filed: Nov. 25, 2024
(86) PCT No.: PCT/CN2024/134242

§ 371 Date: Oct. 6, 2025

(30) Foreign Application Priority Data
Dec. 4, 2023 (CN) 202311649555.4

(51) Int. Cl. H05K 7/20; H05K 7/14

(52) U.S. Cl. CPC H05K 7/20272; H05K 7/1415; H05K 7/20254

(57) ABSTRACT

A cooling apparatus for multi-chip/multi-module heat dissipation is provided. The cooling apparatus includes a plurality of liquid cooling assemblies, a first liquid distributor, and a second liquid distributor. Each liquid cooling assembly includes a heat exchange unit, a liquid inlet pipe, and a liquid outlet pipe, the heat exchange unit covers a corresponding computing module to exchange heat with the corresponding computing module, the liquid inlet pipe is connected to the heat exchange unit to supply a low-temperature cooling liquid to the heat exchange unit, and the liquid outlet pipe is connected to the heat exchange unit to return a heated cooling liquid. The first liquid distributor is disposed on a case and connected to the liquid inlet pipe of each liquid cooling assembly. The second liquid distributor is disposed on the case and connected to the liquid outlet pipe of each liquid cooling assembly.

### CROSS-REFERENCE

The present application is a U.S. National Stage Application based on International Patent Application No. PCT/CN2024/134242, filed on Nov. 25, 2024, which claims priority to Chinese Patent Application No. 202311649555.4, filed on Dec. 4, 2023, and entitled “COOLING APPARATUS FOR MULTI-CHIP/MULTI-MODULE HEAT DISSIPATION”, the contents of which are hereby incorporated by reference in their entireties.

### TECHNICAL FIELD

Embodiments of the present disclosure generally relate to the field of electronic device cooling technologies, and more specifically, to a cooling apparatus for multi-chip/multi-module heat dissipation and a chassis including such a cooling apparatus.

### BACKGROUND

With the continuous improvement of computing power requirements, the power consumption of a computing chip (also referred to as a computing module) is getting higher and higher, and computing chips of 500 W, 700 W, or even over one kilowatt have already appeared. In addition, the simultaneous application of multiple chips or modules in a system is also relatively common, such as a graphics processing unit (GPU) system in which eight GPU modules coexist. Other types of chips, such as a central processing unit (CPU) and an embedded neural-network processing unit (NPU), may also have similar applications.

In a high-power consumption system with multiple chips or modules, a cold plate liquid cooling solution is usually used for heat dissipation. However, due to the large number of chips or modules, the number of liquid cooling pipelines is large and the connection relationship is complex, and it is impossible to independently maintain a single chip or module. Usually, in order to maintain one chip or module, it is necessary to remove all cold plates of all chips or modules. In addition, the GPU module has a high failure rate and frequent maintenance operations, and some GPU chips are unpackaged bare chips, which increases the risk of damage to the chips or modules during the maintenance process.

In addition, in a conventional cold plate liquid cooling solution, a hybrid solution of series and parallel connection is mostly used, and there is a situation of chip temperature cascade. Under the condition of a certain main pipe diameter size, there is a bottleneck in the heat dissipation capability, flow resistance, etc. of the chip.

### SUMMARY

In a first aspect of the present disclosure, a cooling apparatus for multi-chip/multi-module heat dissipation is provided. The cooling apparatus is placed in a chassis, and the chassis includes a case and a plurality of computing modules disposed in the case, where the cooling apparatus includes: a plurality of liquid cooling assemblies, each liquid cooling assembly including a heat exchange unit, a liquid inlet pipe, and a liquid outlet pipe, the heat exchange unit covering a corresponding computing module to exchange heat with the corresponding computing module, the liquid inlet pipe being connected to the heat exchange unit to supply a low-temperature cooling liquid to the heat exchange unit, and the liquid outlet pipe being connected to the heat exchange unit to return a heated cooling liquid; a first liquid distributor disposed on the case and connected to the liquid inlet pipe of each of the plurality of liquid cooling assemblies to supply the low-temperature cooling liquid; and a second liquid distributor disposed on the case and connected to the liquid outlet pipe of each of the plurality of liquid cooling assemblies to collect the heated cooling liquid.

In a second aspect of the present disclosure, a chassis is provided. The chassis includes the cooling apparatus of the first aspect of the present disclosure, the case, and the plurality of computing modules, each computing module being covered by a corresponding heat exchange unit in the cooling apparatus.

It should be understood that the content described in this section is not intended to identify key or essential features of embodiments of the present disclosure, nor is it intended to limit the scope of the present disclosure. Other features of the present disclosure will be readily envisaged through the following description.

### BRIEF DESCRIPTION OF THE DRAWINGS

The above and other features, advantages and aspects of the embodiments of the present disclosure will become more apparent in combination with the drawings and with reference to the following detailed description. In the drawings, the same or similar reference symbols refer to the same or similar elements, where:

FIG. 1 shows a perspective schematic view of a chassis according to some embodiments of the present disclosure;

FIG. 2 shows a structural schematic view of the chassis shown in FIG. 1 as viewed in a height direction;

FIG. 3 shows a perspective schematic view of the chassis shown in FIG. 1 as viewed in a width direction;

FIG. 4 shows a perspective schematic view of a cooling apparatus in the chassis shown in FIG. 1;

FIG. 5 shows a schematic diagram of pipeline connection of the cooling apparatus shown in FIG. 4;

FIG. 6 shows a partial structural schematic view of a liquid cooling assembly in the cooling apparatus shown in FIG. 4;

FIG. 7 shows a perspective schematic view of a chassis according to some embodiments of the present disclosure; and

FIGS. 8 to 11 show example processes of maintaining a single computing module according to some embodiments of the present disclosure.

Description of reference symbols in the drawings:
100 chassis;
200 cooling apparatus;
211 liquid supply pipe;
212 liquid return pipe;
221 first liquid distributor;
222 second liquid distributor;
24 liquid cooling assembly;
240 pipeline;
2401 liquid inlet pipe;
2403 bent portion;
241 heat exchange unit;
242 handle;
243 pipe clamp;
2431 first clamping position;
2432 second clamping position;
300 case;
400 cross beam;
500 computing module;
600 switching module;
700 main board;
800 additional cooling unit.

### DETAILED DESCRIPTION OF EMBODIMENTS

Embodiments of the present disclosure will be described in more detail below with reference to the drawings. Although embodiments of the present disclosure are shown in the drawings, it should be understood that the present disclosure may be implemented in various forms and should not be limited to the embodiments set forth herein. Instead, these embodiments are provided for a thorough and complete understanding of the present disclosure, and the scope of the present disclosure may be fully communicated to those skilled in the art.

The term “include/comprise” and its variants used herein represent open-ended inclusions, that is, “include/comprise but not limited to”. Unless otherwise stated, the term “or” represents “and/or”. The term “based on” represents “at least partially based on”. The terms “an example embodiment” and “an embodiment” represent “at least one example embodiment”. The term “another embodiment” represents “at least one other embodiment”. The terms “first”, “second”, etc. may refer to different or same objects.

As mentioned above, in a conventional high-power consumption system with multiple chips or modules, it is impossible to independently maintain a single chip or module. Usually, in order to maintain one chip or module, it is necessary to remove all cold plates of all chips or modules. In addition, in a conventional cold plate liquid cooling solution, there is a situation of chip temperature cascade, and under the condition of a certain main pipe diameter size, there is a bottleneck in the heat dissipation capability, flow resistance, etc. of the chip.

Embodiments of the present disclosure provide a cooling apparatus for multi-chip/multi-module heat dissipation and a chassis including such a cooling apparatus. For each computing module in the chassis, a corresponding liquid cooling assembly is separately provided, and a heat exchange unit of each liquid cooling assembly is directly connected to liquid distributors via a liquid inlet pipe and a liquid outlet pipe, thereby solving the problem that a chip or a module cannot be maintained individually, realizing individual maintenance of the chip or the module, reducing the risk of damage to the chip or the module caused by maintenance, and realizing rapid individual maintenance. In addition, the solution may also solve the problem of chip temperature cascade, improve the heat dissipation capability of the chip under the condition of a certain main pipe diameter size, and reduce the system flow resistance. The principles of the present disclosure will be described in detail below with

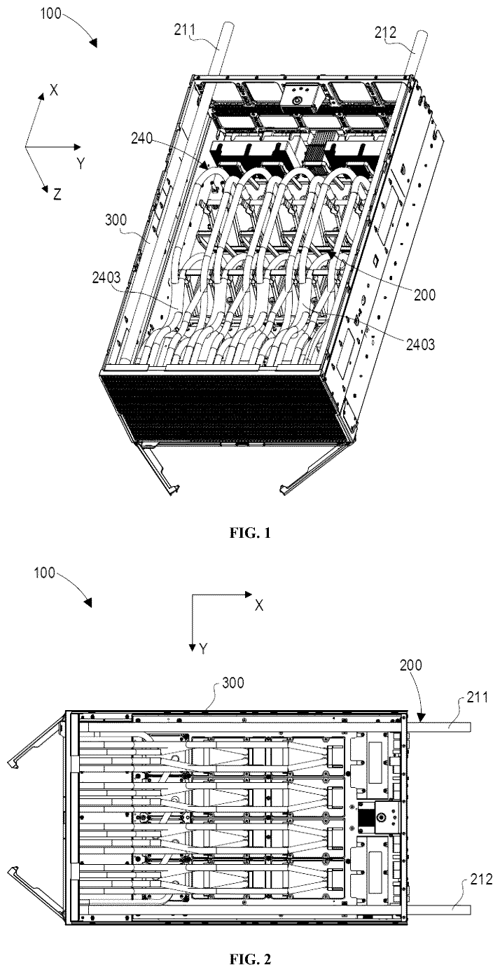

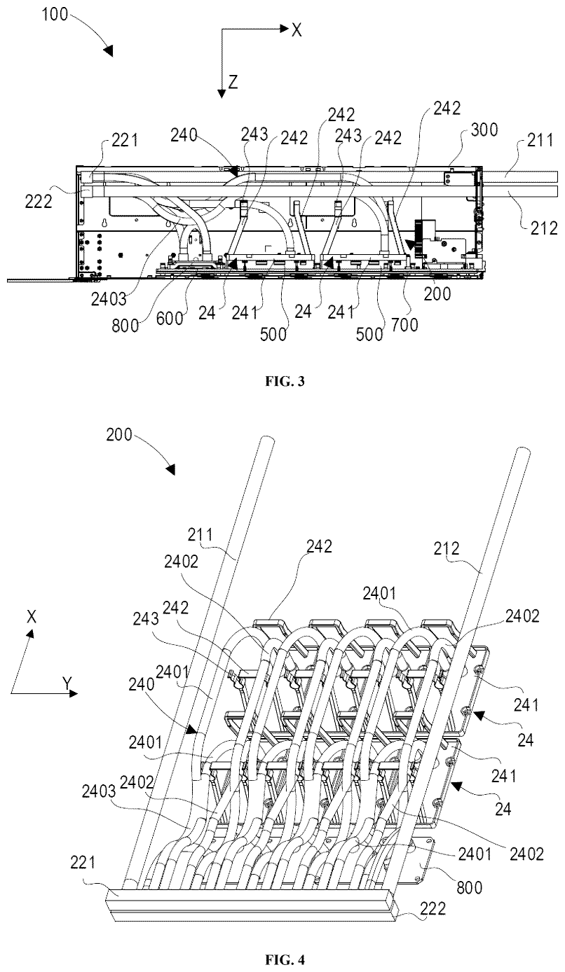

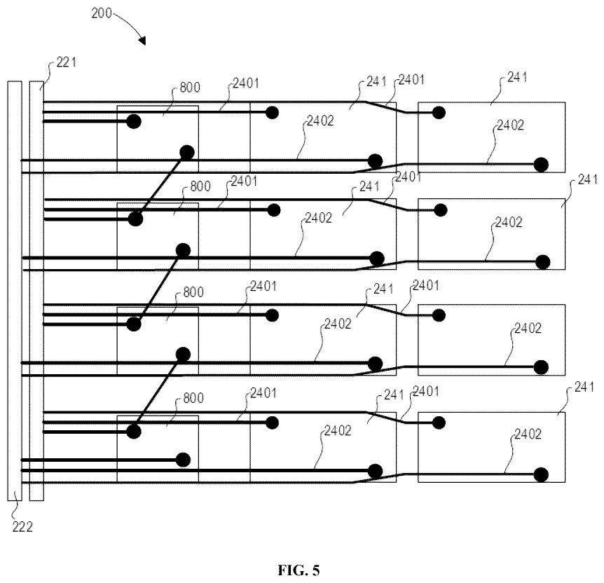

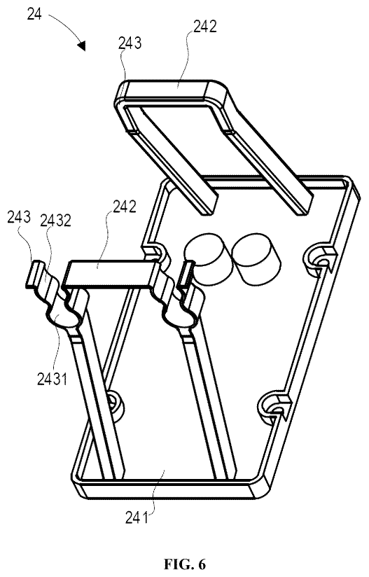

First, referring to FIGS. 1 to 6, FIG. 1 shows a perspective schematic view of a chassis 100 according to some embodiments of the present disclosure, FIG. 2 shows a structural schematic view of the chassis 100 shown in FIG. 1 as viewed in a height direction Z, FIG. 3 shows a perspective schematic view of the chassis 100 shown in FIG. 1 as viewed in a width direction Y, FIG. 4 shows a perspective schematic view of a cooling apparatus 200 in the chassis 100 shown in FIG. 1, FIG. 5 shows a schematic diagram of pipeline connection of the cooling apparatus 200 shown in FIG. 4, and FIG. 6 shows a partial structural schematic view of a liquid cooling assembly 24 in the cooling apparatus 200 shown in FIG. 4.

As shown in FIGS. 1 to 6, the chassis 100 described herein includes a case 300, a main board 700, a plurality of computing modules 500, and a cooling apparatus 200. The case 300 has an internal space for accommodating and/or supporting various components of the chassis 100, such as the main board 700, the computing modules 500, the cooling apparatus 200, and some other components. The chassis 100 may also be referred to as a node herein. In an embodiment, as shown in FIGS. 1 to 3, the case 300 may have a length direction X, the width direction Y, and the height direction Z.

In embodiments of the present disclosure, the length direction X, the width direction Y, and the height direction Z are used to more clearly describe the structure of the chassis 100 and the relative positional relationship between various components. It should be understood that when the chassis 100 is placed in other orientations, the length direction X, the width direction Y, and the height direction Z may be changed accordingly. In addition, the chassis 100 described herein may be a separately provided chassis, or a chassis integrated in a whole cabinet, which is not limited in embodiments of the present disclosure.

As shown in FIG. 3, the main board 700 is disposed in the case 300 for supporting various electronic components of the chassis 100, such as the computing modules 500. The computing modules 500 are disposed on the main board 700 for implementing corresponding computing functions. The main board 700 may include a printed circuit board or various conventional or future-available substrates. In an embodiment, the computing module 500 may include at least one of a GPU, a CPU, or an NPU. In other embodiments, the computing module 500 may include other electronic components that may generate a large amount of heat during operation, and these implementations also fall within the scope of the present disclosure.

In embodiments of the present disclosure, as shown in FIGS. 1 to 5, the cooling apparatus 200 includes a plurality of liquid cooling assemblies 24. Each liquid cooling assembly 24 includes a heat exchange unit 241, a liquid inlet pipe 2401, and a liquid outlet pipe 2402. The liquid inlet pipe 2401 and the liquid outlet pipe 2402 are used for circulating a cooling liquid, which may also be collectively referred to as a pipeline 240 herein. The heat exchange unit 241 covers a corresponding computing module 500 to exchange heat with the corresponding computing module 500. As an example, the heat exchange unit 241 may be formed as a cold plate, and the cold plate is directly connected to the corresponding computing module 500 through a heat conducting material. It should be understood that the heat exchange unit 241 may also include other forms of heat exchange components, and these implementations also fall within the scope of the present disclosure. The liquid inlet pipe 2401 is connected to a corresponding heat exchange unit 241 to supply a low-temperature cooling liquid to the heat exchange unit 241. The cooling liquid mentioned herein may include water or various conventional or future-available cooling liquids, which all fall within the scope of the present disclosure. The liquid outlet pipe 2402 is connected to a corresponding heat exchange unit 241 to return a heated cooling liquid. The heat exchange unit 241 may exchange heat with the corresponding computing module 500 using the low-temperature cooling liquid, thereby absorbing heat generated by the computing module 500 during operation. After absorbing the heat, the temperature of the low-temperature cooling liquid will rise, becoming the heated cooling liquid, and the heat exchange unit 241 may return the heated cooling liquid via the liquid outlet pipe 2402.

In embodiments of the present disclosure, as shown in FIGS. 3 to 5, the cooling apparatus 200 further includes a first liquid distributor 221 and a second liquid distributor 222. The first liquid distributor 221 is disposed on the case 300 and connected to the liquid inlet pipe 2401 of each of the plurality of liquid cooling assemblies 24 to supply the low-temperature cooling liquid to the liquid inlet pipe 2401. In other words, the liquid inlet pipes 2401 of all liquid cooling assemblies 24 may be connected in parallel to the first liquid distributor 221 to receive the low-temperature cooling liquid from the first liquid distributor 221 and supply the low-temperature cooling liquid to the heat exchange units 241. In an embodiment, as shown in FIGS. 1 to 4, the cooling apparatus 200 further includes a liquid supply pipe 211. The liquid supply pipe 211 may be connected to an external cold source to receive the low-temperature cooling liquid from the external cold source and supply the low-temperature cooling liquid to the first liquid distributor 221. The second liquid distributor 222 is disposed on the case 300 and connected to the liquid outlet pipe 2402 of each of the plurality of liquid cooling assemblies 24 to collect the heated cooling liquid returned from the liquid outlet pipe 2402. In other words, the liquid outlet pipes 2402 of all liquid cooling assemblies 24 may be connected in parallel to the second liquid distributor 222 to return the heated cooling liquid received from the heat exchange units 241 to the second liquid distributor 222. In an embodiment, as shown in FIGS. 1 to 4, the cooling apparatus 200 further includes a liquid return pipe 212. The liquid return pipe 212 may be connected to the external cold source to return the heated cooling liquid to the external cold source for cooling, thereby realizing the circulation of the cooling liquid.

In embodiments of the present disclosure, for each computing module 500 in the chassis 100, a corresponding liquid cooling assembly 24 is separately provided, and the heat exchange unit 241 of each liquid cooling assembly 24 is directly connected to the liquid distributors via the liquid inlet pipe 2401 and the liquid outlet pipe 2402, thereby solving the problem that the computing module 500 cannot be maintained individually, realizing individual maintenance of the computing module 500, and reducing the risk of damage to the computing module 500 caused by maintenance. In addition, the solution may also solve the problem of temperature cascade of the computing module 500, improve the heat dissipation capability of the computing module 500 under the condition of a certain main pipe diameter size, and reduce the system flow resistance.

In some embodiments, as shown in FIGS. 3 to 5, the first liquid distributor 221 and the second liquid distributor 222 are disposed side by side at a first end of the case 300 in the length direction X and adjacent to a top side of the case 300 in the height direction Z. With this arrangement, the redundant design of the pipeline 240 of the liquid cooling assembly 24 and the turnover design of the heat exchange unit 241 may be supported. This will be described in further detail below with reference to FIGS. 8 to 11.

In an embodiment, as shown in FIGS. 3 to 5, the heat exchange units 241 of the plurality of liquid cooling assemblies 24 are arranged in two rows, and each row of heat exchange units 241 includes four heat exchange units 241, corresponding to four computing modules 500. Each row of heat exchange units 241 is disposed in the case 300 side by side in the width direction Y of the case 300. Herein, this arrangement will be taken as an example to describe the principle of the present disclosure. However, it should be understood that the heat exchange units 241 of the plurality of liquid cooling assemblies 24 may be arranged in more or less rows, for example, one row, three rows, and so on. Similarly, each row of heat exchange units 241 is disposed in the case 300 side by side in the width direction Y of the case 300. In addition, each row of heat exchange units 241 may include more or less heat exchange units 241, such as three, five, and so on.

It should be noted that the numbers, values, etc. mentioned above and possibly mentioned elsewhere in the present disclosure are illustrative and are not intended to limit the scope of the present disclosure in any way. Any other suitable numbers and values are possible.

It should be understood that the installation positions of the first liquid distributor 221 and the second liquid distributor 222 on the case 300 may be adjusted adaptively according to the actual needs of different cold plate systems. In some embodiments, the first liquid distributor 221 and the second liquid distributor 222 may be disposed at other positions of the first end of the chassis 100, for example, adjacent to a middle part or even a bottom part of the case 300 in the height direction Z. In some other embodiments, one of the first liquid distributor 221 and the second liquid distributor 222 may be adjacent to the top of the case 300 in the height direction Z, while the other liquid distributor may be adjacent to the middle or bottom of the case 300 in the height direction Z. In some other embodiments, the first liquid distributor 221 and the second liquid distributor 222 may be connected to the case 300 through additional supports. These example implementations of the installation positions of the first liquid distributor 221 and the second liquid distributor 222 all fall within the scope of the present disclosure.

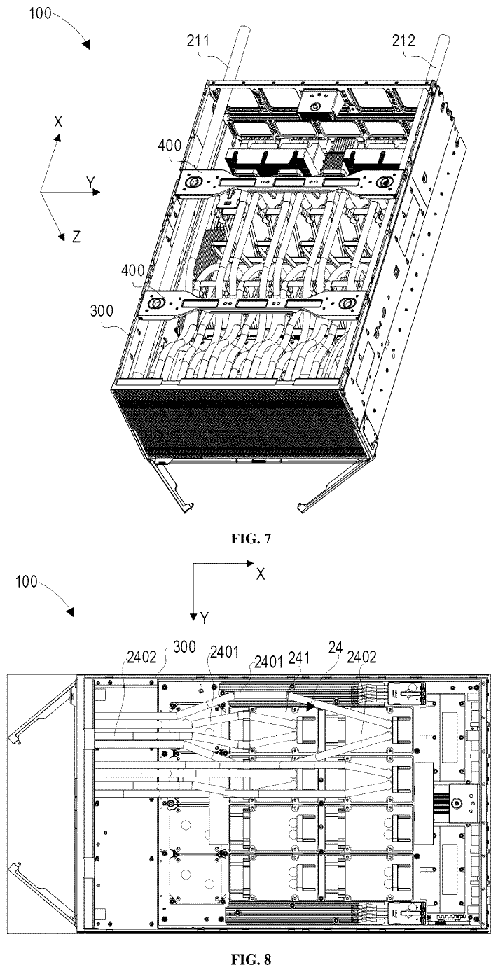

In some embodiments, as shown in FIGS. 3, 4 and 6, each liquid cooling assembly 24 further includes at least one handle 242 disposed on a side of the heat exchange unit 241 away from the corresponding computing module 500 to lift and place the heat exchange unit 241. When a certain computing module 500 needs to be maintained, the heat exchange unit 241 corresponding to the computing module 500 may be lifted by the handle 242, and the computing module 500 may be removed. Subsequently, the heat exchange unit 241 may be placed upside down on a support member (e.g., a cross beam 400 which will be described below in conjunction with FIG. 7) to facilitate the replacement of the computing module 500.

In an embodiment, as shown in FIG. 6, the heat exchange unit 241 is provided with two handles 242, and the two handles 242 are respectively disposed close to adjacent ends of the heat exchange unit 241. When a certain computing module 500 needs to be maintained, the heat exchange unit 241 may be lifted by one of the handles 242, and the computing module 500 may be removed. Subsequently, the heat exchange unit 241 may be placed upside down on the support member using an inclined surface of the other one of the handles 242 or other fixing mechanisms to facilitate the replacement of the computing module 500.

It should be understood that more or less handles 242 may be disposed on the heat exchange unit 241, for example, one, three, and so on. In addition, according to design requirements, the handle 242 may also be disposed at other positions on the heat exchange unit 241, and these implementations all fall within the scope of the present disclosure.

In some embodiments, as shown in FIGS. 3, 4 and 6, at least one handle 242 is provided with a pipe clamp 243 for supporting the liquid inlet pipe 2401 and/or the liquid outlet pipe 2402. The pipe clamp 243 may not only be used to fix the pipeline 240 of the corresponding heat exchange unit 241, but also in a case where a certain computing module 500 needs to be maintained, the pipe clamps 243 of adjacent heat exchange units 241 in the same row may be used to fix the pipelines 240 of other heat exchange units 241, so as to facilitate the disassembly and assembly operations of the heat exchange module 500 to be maintained. This will be described in detail below with reference to FIGS. 8 to 11.

In some embodiments, as shown in FIG. 6, the pipe clamp 243 includes a first clamping position 2431 and a second clamping position 2432 that are communicated with each other, and the first clamping position 2431 is closer to the heat exchange unit 241 than the second clamping position 2432. In a case where a certain computing module 500 needs to be maintained, the first clamping position 2431 of the pipe clamp 243 of an adjacent heat exchange unit 241 in the same row may be used to fix its own pipeline 240, and the second clamping position 2432 of the pipe clamp 243 of an adjacent heat exchange unit 241 may be used to fix the pipelines 240 of other heat exchange units 241, so as to facilitate the disassembly and assembly operations of the heat exchange module 500 to be maintained. This will be described in detail below with reference to FIGS. 8 to 11.

In some embodiments, as shown in FIGS. 3 and 4, the liquid inlet pipe 2401 and the liquid outlet pipe 2402 are respectively provided with at least one bent portion 2403. By providing at least one bent portion 2403, the pipeline 240 between the heat exchange unit 241 and the liquid distributors may have a redundant amount of an appropriate length, which is used for the avoidance of the pipeline 240 and the turning over of the heat exchange unit 241 when the single computing module 500 is maintained. As an example, a single bent portion 2403 may be disposed adjacent to the first liquid distributor 221 and the second liquid distributor 222 and bent toward the bottom of the case 300. It should be understood that the bent portion 2403 may be disposed at other positions on the pipeline 240, may be other numbers, or may be bent in other forms, and these implementations all fall within the scope of the present disclosure.

In some embodiments, the case 300 may be provided with a pipe clamp 243 for supporting the liquid inlet pipe 2401 and/or the liquid outlet pipe 2402. In a case where a certain computing module 500 needs to be maintained, the pipe clamp 243 on the case 300 may also be used to fix the pipeline 240 that needs to be avoided, so as to facilitate the disassembly and assembly operations of the heat exchange module 500 to be maintained.

In some embodiments, as shown in FIGS. 3 to 5, the chassis 100 further includes a plurality of switching modules 600, and the cooling apparatus 200 further includes a plurality of additional cooling units 800. The plurality of switching modules 600 are disposed on the main board 700 and closer to the first end of the case 300 than the plurality of computing modules 500. The plurality of additional cooling units 800 respectively cover corresponding switching modules 600 to exchange heat with the corresponding switching modules 600. The plurality of switching modules 600 are mainly responsible for the transmission and exchange of data and/or signals required by the computing module 500, and generate less heat during operation. Therefore, the plurality of additional cooling units 800 may be connected in series between the first liquid distributor 221 and the second liquid distributor 222 via pipelines to realize the cooling of each switching module 600 in a cascading manner.

FIG. 8 shows a perspective schematic view of a chassis according to some embodiments of the present disclosure. In some embodiments, as shown in FIG. 8, the chassis 100 further includes at least one cross beam 400. The at least one cross beam 400 is detachably connected to a top side of the case 300 in the height direction Z to enhance the strength of the case 300. Each cross beam 400 extends along the width direction Y of the case 300. The cross beam 400 may be connected to the case 300 by clamping or any suitable detachable connection method. In addition, when a certain computing module 500 needs to be maintained, the cross beam 400 may also play a role in supporting the computing module 500 to be maintained and the corresponding heat exchange unit 241, which will be further described below.

In some embodiments, in order to more stably support the computing module 500 to be maintained and the corresponding heat exchange unit 241 on the cross beam 400, the cross beam 400 may be provided with a limiting member (not shown) for clamping the liquid cooling assembly 24 corresponding to the computing module 500 to be maintained. In a case where the heat exchange unit 241 is placed upside down on the cross beam 400, the heat exchange unit 241 may be clamped into the limiting member, so that the liquid cooling assembly 24 is supported more stably and reliably.

In some embodiments, at least one cross beam 400 may be provided with a pipe clamp 243 for supporting the liquid inlet pipe 2401 and/or the liquid outlet pipe 2402. In a case where a certain computing module 500 needs to be maintained, the pipe clamp 243 on the cross beam 400 may also be used to fix the pipeline 240 that needs to be avoided, so as to facilitate the disassembly and assembly operations of the heat exchange module 500 to be maintained.

Hereinafter, an example process of maintaining a single computing module 500 will be described with reference to FIGS. 8 to 11. In example described herein, the pipelines 240 in the chassis 100 are designed in three layers, where the first layer includes the pipelines 240 of the heat exchange units 241 corresponding to rear-row computing modules 500, the second layer includes the pipelines 240 of the heat exchange units 241 corresponding to front-row computing modules 500, and the third layer includes the pipelines 240 of the additional cooling units 800 corresponding to the switching modules 600. FIGS. 8 to 11 show an example process of maintaining a single computing module 500 in the front-row computing modules 500. Herein, the maintenance process will be described by taking the computing module 500 (which may also be referred to as a first computing module herein for ease of understanding) close to the top side in the orientation shown in FIG. 8 in the front-row computing modules 500 as an example. It should be understood that other computing modules 500 in the front-row computing modules 500 may be maintained in a similar process.

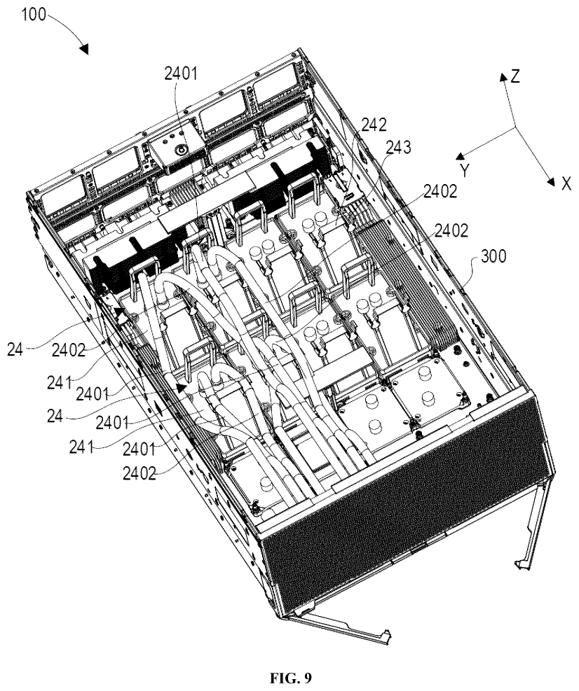

As shown in FIGS. 8 and 9, the cross beam 400 on the case 300 is first removed to facilitate operations on the heat exchange unit 241 and the computing module 500. In order to more clearly show the process of maintaining the single computing module 500 in the front-row computing modules 500, some pipelines 240 are omitted in FIGS. 8 and 9.

As shown in FIGS. 8 and 9, after the cross beam 240 is removed, the pipeline 240 of the heat exchange unit 241 corresponding to a rear-row computing module 500 (which may also be referred to as a second computing module for ease of understanding) adjacent to the front-row computing module 500 to be maintained (i.e., the first computing module) in the length direction X of the case 300 is pushed apart, and is respectively fixed on the pipe clamp 243 on the case 300 and the pipe clamp 243 of the heat exchange unit 241 corresponding to a computing module 500 (which may also be referred to as a third computing module for ease of understanding) adjacent to the front-row computing module 500 to be maintained (i.e., the first computing module) in the width direction Y of the case 300. For example, the liquid inlet pipe 2401 in the pipeline 240 may be fixed on the pipe clamp 243 on the case 300, and the liquid outlet pipe 2402 in the pipeline 240 is fixed on the pipe clamp 243 of the heat exchange unit 241 corresponding to the third computing module. Before the pipeline 240 is fixed to the pipe clamps 243, the pipeline 240 of the heat exchange unit 241 corresponding to the third computing module has been pre-pressed into the first clamping position 2431 of its pipe clamp 243, so that the liquid outlet pipe 2402 in the pipeline of the first computing module may be pressed into the second clamping position 2432 of the pipe clamp 243 of the heat exchange unit 241 corresponding to the third computing module. At this point, there is no pipeline 240 shielding above the heat exchange unit 241 corresponding to the front-row computing module 500 to be maintained (i.e., the first computing module).

Subsequently, the fixing screws between the front-row computing module 500 to be maintained (i.e., the first computing module) and the main board 700 are disassembled, so that the front-row computing module 500 to be maintained is disengaged from the main board 700. The heat exchange unit 241 and the computing module 500 are lifted by the handle 242, and the heat exchange unit 241 is separated from the computing module 500.

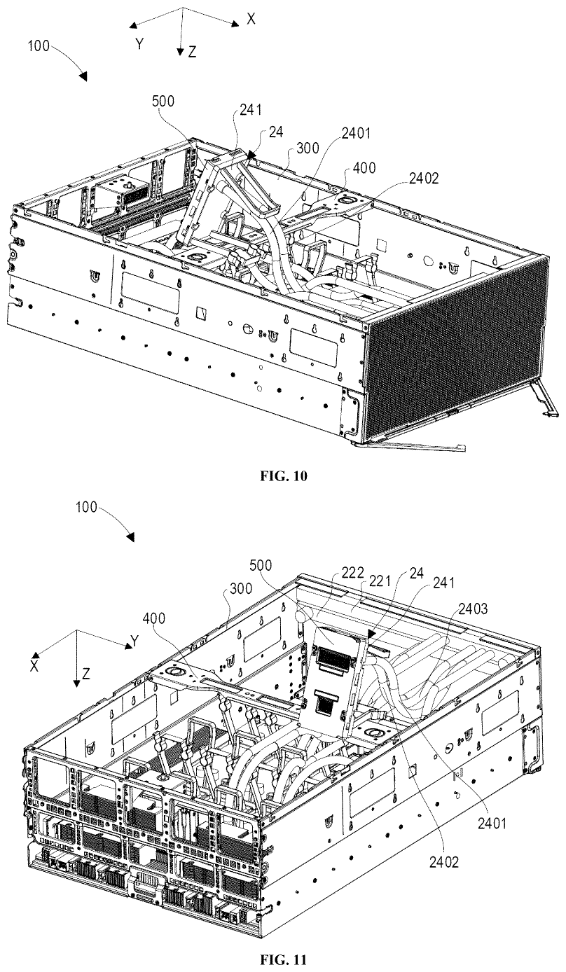

Subsequently, as shown in FIGS. 10 and 11, the cross beam 400 is installed above the computing module 500 to be maintained, and after the heat exchange unit 241 is turned over, the heat exchange unit 241 is placed upside down on the cross beam 400 using the inclined surface of the handle 242 or other fixing mechanisms. At this point, a side of the heat exchange unit 241 that is adapted to be in contact with the computing module 500 faces upward, and the pipeline 240 of the heat exchange unit 241 is in a naturally bent state.

Subsequently, a new computing module 500 is installed on the main board 700 by screws, and a heat conducting material is coated on the computing module 500. Subsequently, the heat exchange unit 241 is lifted by the handle 242 and installed on the new computing module 500.

Subsequently, the pipeline 240 of the heat exchange unit 241 corresponding to the rear-row computing module 500 (i.e., the second computing module) adjacent to the front-row computing module 500 to be maintained (i.e., the first computing module) is reset, and the cross beam 400 is reset. So far, the maintenance process of a single computing module 500 in the front row is completed.

Next, the maintenance process of a single computing module in the rear-row computing modules 500 will be described. Since there is no pipeline 240 shielding above the rear-row computing module 500, the maintenance process of the rear-row computing module 500 does not need to fix the pipeline 240 of the heat exchange unit 241 corresponding to the computing module 500 to be maintained to the pipe clamp 243 of an adjacent heat exchange unit 241. An example maintenance process of a single computing module in the rear-row computing modules 500 is as follows.

First, the cross beam 400 on the case 300 is removed to facilitate operations on the heat exchange unit 241 and the computing module 500.

After the cross beam 240 is removed, the pipeline 240 of the heat exchange unit 241 corresponding to the rear-row computing module 500 to be maintained is fixed in the pipe clamps 243.

Subsequently, the fixing screws between the rear-row computing module 500 to be maintained and the main board 700 are disassembled, so that the rear-row computing module 500 to be maintained is disengaged from the main board 700. The heat exchange unit 241 and the computing module 500 are lifted by the handle 242, and the heat exchange unit 241 is separated from the computing module 500.

Subsequently, the cross beam 400 is installed above the computing module 500 to be maintained, and after the heat exchange unit 241 is turned over, the heat exchange unit 241 is placed upside down on the cross beam 400 using the inclined surface of the handle 242 or other fixing mechanisms. At this point, a side of the heat exchange unit 241 that is adapted to be in contact with the computing module 500 faces upward, and the pipeline 240 of the heat exchange unit 241 is in a naturally bent state.

Subsequently, a new computing module 500 is installed on the main board 700 by screws, and a heat conducting material is coated on the computing module 500. Subsequently, the heat exchange unit 241 is lifted by the handle 242 and installed on the new computing module 500.

Subsequently, the pipeline 240 of the heat exchange unit 241 corresponding to the rear-row computing module 500 to be maintained is reset, and the cross beam 400 is reset. So far, the maintenance process of a single computing module 500 in the rear row is completed.

It is described above that the heat exchange unit 241 is turned back and forth in the length direction X of the case 300 when the computing module 500 is maintained, which is only an example implementation of the present disclosure. In some embodiments, when the computing module 500 is maintained, the heat exchange unit 241 may be turned left and right, i.e., laterally, in the width direction Y of the case 300.

According to embodiments of the present disclosure, the individual maintenance of the computing module 500 is realized, the risk of damage to the computing module 500 caused by maintenance is reduced, and the efficiency of maintenance is improved by rapid individual maintenance. In addition, the full parallel topology scheme of the pipeline eliminates the temperature cascade of the computing module cooling, improves the heat dissipation capability of the chip under a certain main pipe diameter size, and reduces the system flow resistance.

Embodiments of the present disclosure are also reflected in the following examples.

Example 1. A cooling apparatus for multi-chip/multi-module heat dissipation, the cooling apparatus being placed in a chassis, and the chassis including a case and a plurality of computing modules disposed in the case, wherein the cooling apparatus includes:
a plurality of liquid cooling assemblies, each liquid cooling assembly including a heat exchange unit, a liquid inlet pipe, and a liquid outlet pipe, the heat exchange unit covering a corresponding computing module to exchange heat with the corresponding computing module, the liquid inlet pipe being connected to the heat exchange unit to supply a low-temperature cooling liquid to the heat exchange unit, and the liquid outlet pipe being connected to the heat exchange unit to return a heated cooling liquid;
a first liquid distributor disposed on the case and connected to the liquid inlet pipe of each of the plurality of liquid cooling assemblies to supply the low-temperature cooling liquid; and
a second liquid distributor disposed on the case and connected to the liquid outlet pipe of each of the plurality of liquid cooling assemblies to collect the heated cooling liquid.

Example 2. The cooling apparatus of Example 1, the first liquid distributor and the second liquid distributor are disposed at a first end of the case in a length direction, the heat exchange units of the plurality of liquid cooling assemblies are arranged in one or more rows, and each row of heat exchange units is disposed in the case side by side in a width direction of the case.

Example 3. The cooling apparatus of Example 2, the first liquid distributor and the second liquid distributor are disposed side by side at the first end of the case adjacent to a top side of the case in a height direction, and respectively extend along the width direction of the case.

Example 4. The cooling apparatus of any one of Examples 1 to 3, each liquid cooling assembly further includes at least one handle disposed on a side of the heat exchange unit away from the corresponding computing module to lift and place the heat exchange unit.

Example 5. The cooling apparatus of Example 4, the at least one handle is provided with a pipe clamp for supporting the liquid inlet pipe and/or the liquid outlet pipe.

Example 6. The cooling apparatus of Example 5, the heat exchange units of the plurality of liquid cooling assemblies are arranged in two rows, and the pipe clamp includes a first clamping position and a second clamping position that are communicated with each other, the first clamping position being closer to the heat exchange unit than the second clamping position.

Example 7. The cooling apparatus of Example 2, the chassis further includes a plurality of switching modules, and the cooling apparatus further includes a plurality of additional cooling units, the plurality of switching modules are disposed in the case and closer to the first end of the case than the plurality of computing modules, the plurality of additional cooling units respectively cover corresponding switching modules to exchange heat with the corresponding switching modules, and the plurality of additional cooling units are connected in series between the first liquid distributor and the second liquid distributor via pipelines.

Example 8. The cooling apparatus of any one of Examples 1 to 3 and 5 to 7, the liquid inlet pipe and the liquid outlet pipe are respectively provided with at least one bent portion.

Example 9. A chassis, including:
the cooling apparatus of any one of Examples 1 to 8;
the case; and
the plurality of computing modules, each computing module being covered by a corresponding heat exchange unit in the cooling apparatus.

Example 10. The chassis of Example 9, further including at least one cross beam detachably connected to a top side of the case in a height direction and adapted to support the liquid cooling assembly corresponding to a computing module to be maintained.

Example 11. The chassis of Example 10, the at least one cross beam is provided with a limiting member for clamping the liquid cooling assembly corresponding to the computing module to be maintained.

Example 12. The chassis of Example 10, the at least one cross beam is provided with a pipe clamp for supporting the liquid inlet pipe and/or the liquid outlet pipe.

Example 13. The chassis of Example 9, the case is provided with a pipe clamp for supporting the liquid inlet pipe and/or the liquid outlet pipe.

The embodiments of the present disclosure have been described above, and the above description is illustrative, non-exhaustive, and not limited to the disclosed embodiments. Without departing from the scope and spirit of the described embodiments, many modifications and changes will be apparent to those of ordinary skill in the art. The choice of terms used herein is intended to best explain the principles, practical applications, or technical improvements to the market of the embodiments, or to enable other ordinary skilled in the art to understand the embodiments disclosed herein.

1-13. (canceled)

14. A cooling apparatus for multi-chip/multi-module heat dissipation, the cooling apparatus being placed in a chassis, and the chassis comprising a case and a plurality of computing modules disposed in the case, wherein the cooling apparatus comprises:
a plurality of liquid cooling assemblies, each liquid cooling assembly comprising a heat exchange unit, a liquid inlet pipe, and a liquid outlet pipe, the heat exchange unit covering a corresponding computing module to exchange heat with the corresponding computing module, the liquid inlet pipe being connected to the heat exchange unit to supply a low-temperature cooling liquid to the heat exchange unit, and the liquid outlet pipe being connected to the heat exchange unit to return a heated cooling liquid;
a first liquid distributor disposed on the case and connected to the liquid inlet pipe of each of the plurality of liquid cooling assemblies to supply the low-temperature cooling liquid; and
a second liquid distributor disposed on the case and connected to the liquid outlet pipe of each of the plurality of liquid cooling assemblies to collect the heated cooling liquid.

15. The cooling apparatus of claim 14, wherein the first liquid distributor and the second liquid distributor are disposed at a first end of the case in a length direction, the heat exchange units of the plurality of liquid cooling assemblies are arranged in one or more rows, and each row of heat exchange units is disposed in the case side by side in a width direction of the case.

16. The cooling apparatus of claim 15, wherein the first liquid distributor and the second liquid distributor are disposed side by side at the first end of the case adjacent to a top side of the case in a height direction, and respectively extend along the width direction of the case.

17. The cooling apparatus of claim 14, wherein each liquid cooling assembly further comprises at least one handle disposed on a side of the heat exchange unit away from the corresponding computing module to lift and place the heat exchange unit.

18. The cooling apparatus of claim 17, wherein the at least one handle is provided with a pipe clamp for supporting the liquid inlet pipe and/or the liquid outlet pipe.

19. The cooling apparatus of claim 18, wherein the heat exchange units of the plurality of liquid cooling assemblies are arranged in two rows, and the pipe clamp comprises a first clamping position and a second clamping position that are communicated with each other, the first clamping position being closer to the heat exchange unit than the second clamping position.

20. The cooling apparatus of claim 15, wherein the chassis further comprises a plurality of switching modules, and the cooling apparatus further comprises a plurality of additional cooling units, the plurality of switching modules are disposed in the case and closer to the first end of the case than the plurality of computing modules, the plurality of additional cooling units respectively cover corresponding switching modules to exchange heat with the corresponding switching modules, and the plurality of additional cooling units are connected in series between the first liquid distributor and the second liquid distributor via pipelines.

21. The cooling apparatus of claim 14, wherein the liquid inlet pipe and the liquid outlet pipe are respectively provided with at least one bent portion.

22. A chassis, comprising:
a case;
a plurality of computing modules disposed in the case; and
a cooling apparatus comprising:
a plurality of liquid cooling assemblies, each liquid cooling assembly comprising a heat exchange unit, a liquid inlet pipe, and a liquid outlet pipe, the heat exchange unit covering a corresponding computing module to exchange heat with the corresponding computing module, the liquid inlet pipe being connected to the heat exchange unit to supply a low-temperature cooling liquid to the heat exchange unit, and the liquid outlet pipe being connected to the heat exchange unit to return a heated cooling liquid;
a first liquid distributor disposed on the case and connected to the liquid inlet pipe of each of the plurality of liquid cooling assemblies to supply the low-temperature cooling liquid; and
a second liquid distributor disposed on the case and connected to the liquid outlet pipe of each of the plurality of liquid cooling assemblies to collect the heated cooling liquid.

23. The chassis of claim 22, further comprising at least one cross beam detachably connected to a top side of the case in a height direction and adapted to support the liquid cooling assembly corresponding to a computing module to be maintained.

24. The chassis of claim 23, wherein the at least one cross beam is provided with a limiting member for clamping the liquid cooling assembly corresponding to the computing module to be maintained.

25. The chassis of claim 23, wherein the at least one cross beam is provided with a pipe clamp for supporting the liquid inlet pipe and/or the liquid outlet pipe.

26. The chassis of claim 22, wherein the case is provided with a pipe clamp for supporting the liquid inlet pipe and/or the liquid outlet pipe.

27. The chassis of claim 22, wherein the first liquid distributor and the second liquid distributor are disposed at a first end of the case in a length direction, the heat exchange units of the plurality of liquid cooling assemblies are arranged in one or more rows, and each row of heat exchange units is disposed in the case side by side in a width direction of the case.

28. The chassis of claim 27, wherein the first liquid distributor and the second liquid distributor are disposed side by side at the first end of the case adjacent to a top side of the case in a height direction, and respectively extend along the width direction of the case.

29. The chassis of claim 22, wherein each liquid cooling assembly further comprises at least one handle disposed on a side of the heat exchange unit away from the corresponding computing module to lift and place the heat exchange unit.

30. The chassis of claim 29, wherein the at least one handle is provided with a pipe clamp for supporting the liquid inlet pipe and/or the liquid outlet pipe.

31. The chassis of claim 30, wherein the heat exchange units of the plurality of liquid cooling assemblies are arranged in two rows, and the pipe clamp comprises a first clamping position and a second clamping position that are communicated with each other, the first clamping position being closer to the heat exchange unit than the second clamping position.

32. The chassis of claim 27, wherein the chassis further comprises a plurality of switching modules, and the cooling apparatus further comprises a plurality of additional cooling units, the plurality of switching modules are disposed in the case and closer to the first end of the case than the plurality of computing modules, the plurality of additional cooling units respectively cover corresponding switching modules to exchange heat with the corresponding switching modules, and the plurality of additional cooling units are connected in series between the first liquid distributor and the second liquid distributor via pipelines.

33. The chassis of claim 22, wherein the liquid inlet pipe and the liquid outlet pipe are respectively provided with at least one bent portion.
